(19) United States
(12) Patent Application Publication
(10) Pub. No.: US 2026/0135061 A1
(43) Pub. Date: May 14, 2026

(54) Charged Particle Beam Device and Method for Estimating Sample Characteristics

(71) Applicant: Hitachi High-Tech Corporation, Minato-ku, Tokyo (JP)

(72) Inventors: Yasuhiro SHIRASAKI, Tokyo (JP); Natsuki TSUNO, Tokyo (JP); Minami UCHIHO, Tokyo (JP); Makoto SAKAKIBARA, Tokyo (JP); Kazufumi YACHI, Tokyo (JP)

(21) Appl. No.: 19/121,480

(22) PCT Filed: Dec. 15, 2022
(86) PCT No.: PCT/JP2022/046201

§ 371 Date: Apr. 16, 2025

(51) Int. Cl. H01J 37/22; H01J 37/147; H01J 37/244; H01J 37/28

(52) U.S. Cl. CPC H01J 37/222; H01J 37/147; H01J 37/226; H01J 37/244; H01J 37/28; H01J 2237/221; H01J 2237/2448; H01J 2237/2817

(57) ABSTRACT

A charged particle beam device includes a charged particle source that irradiates a sample with a charged particle beam, a detector that detects secondary electrons generated from the sample due to irradiation with the charged particle beam, a deflector that deflects the charged particle beam, and an image processing device that generates an image based on irradiation position information on the charged particle beam on the sample and detection intensity by the detector. The image processing device acquires images of the sample in different charging states of the sample, measures a feature of a feature shape that occurs at a boundary between regions of different materials in each of the acquired images, and estimates an electrical or material characteristic of the sample based on the feature.

### TECHNICAL FIELD

The present invention relates to a charged particle beam device that irradiates a sample with a charged particle beam and a method for estimating sample characteristics. In particular, the invention relates to an inspection method and a charged particle beam device for inspecting an electrical characteristic or a material characteristic of the sample.

### BACKGROUND ART

In a charged particle beam device, for example, a scanning electron microscope (hereinafter, abbreviated as SEM), a fine pattern on the order of nanometers can be identified using a focused electron beam. One of SEM observation methods is a voltage contrast method. A voltage contrast is a contrast that reflects a difference in a surface voltage of a sample and reflects conductivity of the sample. A technique for inspecting an electrical characteristic defect of a semiconductor device using this voltage contrast method has been put into practical use. In the inspection of the electrical characteristic defect, a defective portion is specified using brightness of a pattern such as wiring or a plug on an SEM image.

The brightness represents a degree of brightness in a signal of an image or a pixel acquired by the charged particle beam device, and may be referred to as luminance. For example, since a potential during electron beam irradiation is relatively low in a pattern having high conductivity, the brightness is high, and since the potential is high in a pattern having low conductivity, the brightness is low. Thus, a defective part having different conductivity can be detected based on a difference in brightness of an image. As a technique for inspecting an electrical characteristic defect using the voltage contrast method, PTL 1 discloses a method of measuring a dimension, a material, and an electrical characteristic by acquiring an image under an interaction beam irradiation condition according to a characteristic to be inspected in an inspection device using an electron beam.

### CITATION LIST

### Patent Literature

PTL 1: WO2022/059202

### SUMMARY OF INVENTION

### Technical Problem

In the electrical characteristic inspection using the voltage contrast method, it is necessary that an electrical defect of a conductor constituting a plug or wiring to be measured or a dielectric constituting an interlayer film thereof affects a sample potential during SEM observation and appears as a brightness difference on an SEM image.

However, when a resistance value of a measurement target is excessively small, it is difficult to detect a brightness change on the SEM image since a change in a sample potential due to presence or absence of an electrical defect during SEM observation is small. On the contrary, when the resistance value is excessively large as in a case of a dielectric film, the sample potential at the time of SEM observation is high and the brightness change on the SEM image is saturated, and thus detection sensitivity cannot be obtained. That is, in a case of a measurement target where a sample potential change during SEM observation is excessively small or excessively large, the voltage contrast method has low sensitivity to the electrical defect. Accordingly, a technique for inspecting a sample characteristic with high sensitivity is desired.

### Solution to Problem

A charged particle beam device according to an aspect of the present description includes: a charged particle source configured to irradiate a sample with a charged particle beam; a detector configured to detect a secondary electron generated from the sample due to the irradiation with the charged particle beam; a deflector configured to deflect the charged particle beam; and an image processing device configured to generate an image based on irradiation position information on the charged particle beam on the sample and detection intensity by the detector, in which the image processing device acquires images of the sample in different charging states of the sample, measures a feature of a feature shape that occurs at a boundary between regions of different materials in each of the acquired images, and estimates an electrical characteristic or a material characteristic of the sample based on the feature.

### Advantageous Effects of Invention

According to an embodiment of the description, an electrical or material characteristic of a sample can be inspected with high sensitivity. Other problems and novel features will become apparent from description of the present description and the accompanying drawings.

### BRIEF DESCRIPTION OF DRAWINGS

FIG. 1 is an example of a pattern of an observed sample and an SEM image thereof (schematic diagram).

FIG. 2A shows a mechanism by which a third region is generated.

FIG. 2B shows the mechanism by which the third region is generated.

FIG. 3 shows a potential distribution when the sample in FIG. 1 is observed under two different imaging conditions and a brightness distribution in an SEM image associated therewith.

FIG. 4A is a device configuration example of a charged particle beam device in a first embodiment.

FIG. 4B is the device configuration example of the charged particle beam device in the first embodiment.

FIG. 5 is a flowchart showing an example of electrical characteristic measurement in the first embodiment.

FIG. 6 is an example of a graphical user interface (GUI) for setting an imaging condition in the first embodiment.

FIG. 7 shows two different imaging conditions in the first embodiment.

FIG. 8A is an example of a GUI that displays a result of the first embodiment.

FIG. 8B is an example of a GUI that displays a result of the first embodiment.

FIG. 8C is an example of a GUI that displays a result of the first embodiment.

FIG. 8D is an example of a GUI that displays a result of the first embodiment.

FIG. 8E is an example of a GUI that displays a result of the first embodiment.

FIG. 8F is an example of a GUI that displays a result of the first embodiment.

FIG. 8G is an example of a GUI that displays a result of the first embodiment.

FIG. 9A shows a method for extracting a feature indicating a shape from a brightness profile of an SEM image.

FIG. 9B shows the method for extracting the feature indicating the shape from the brightness profile of the SEM image.

FIG. 10 is a device configuration example of a charged particle beam device in a second embodiment.

FIG. 11A is an example of a GUI that displays imaging condition setting and a result in the second embodiment.

FIG. 11B is an example of a GUI that displays imaging condition setting and a result in the second embodiment.

FIG. 12 shows a mechanism used for energy offset measurement of an interface between a semiconductor and a dielectric.

FIG. 13A is an example of a GUI that displays imaging condition setting and a result in a third embodiment.

FIG. 13B is an example of a GUI that displays imaging condition setting and a result in the third embodiment.

FIG. 14 is an observed sample and an SEM image thereof (schematic diagram) in a fourth embodiment.

FIG. 15A is an example of a GUI that displays imaging condition setting and a result in the fourth embodiment.

FIG. 15B is an example of a GUI that displays imaging condition setting and a result in the fourth embodiment.

FIG. 15C is an example of a GUI that displays imaging condition setting and a result in the fourth embodiment.

FIG. 15D is an example of a GUI that displays imaging condition setting and a result in the fourth embodiment.

### DESCRIPTION OF EMBODIMENTS

Hereinafter, embodiments will be described with reference to the accompanying drawings. In the drawings, the same parts are denoted by the same reference signs, and redundant description thereof is appropriately omitted. The accompanying drawings are intended to facilitate the description and understanding of the invention, and it should be noted that shapes, dimensions, ratios, and the like in the drawings may be different from an actual device in some places.

A semiconductor device includes a dielectric region electrically insulated from a pattern made of a metal or a semiconductor that is conductive. Since a boundary of the dielectric region in contact with the pattern made of the metal or the semiconductor has the same potential as a potential of the pattern, a potential gradient is generated in the dielectric region. That is, the potential of the pattern is also reflected in the dielectric region in contact with the pattern made of the metal or the semiconductor.

Since a secondary electron emission amount of the dielectric changes according to the potential, the potential gradient in the dielectric region depending on the pattern potential can be measured as a brightness profile on a scanning electron microscope (SEM) image. That is, by analyzing a shape (feature shape) of the brightness profile on the SEM image at the boundary between the pattern and the dielectric, the potential of the pattern can be calculated, and an electrical characteristic or a material characteristic can be inspected with high sensitivity.

### First Embodiment

In the following embodiment, an example is shown in which an electron beam is used as a charged particle beam. However, the charged particle beam is not limited to the electron beam as long as the charged particle beam can induce charge on a sample. Irradiation with the electron beam to the sample causes signal electrons to be emitted from the sample. An SEM images a surface of the sample by scanning the sample with the electron beam and detecting the signal electrons from the sample. An image thus obtained is called an SEM image.

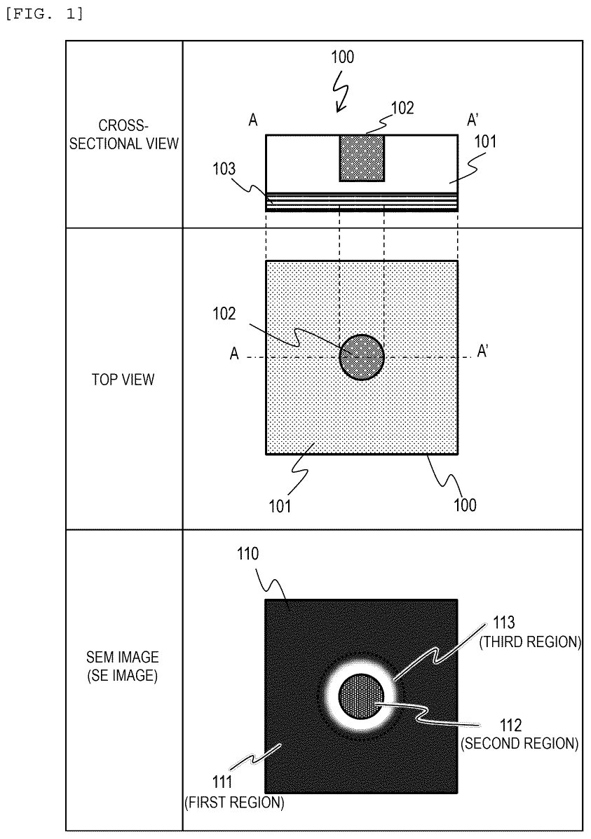

FIG. 1 shows an example of a sample 100 to be inspected. FIG. 1 is a cross-sectional view, a top view, and an SEM image acquired by an SEM of the sample 100. The cross-sectional view shows a cross-section taken along line AA′ in the top view. The sample 100 is formed such that a contact plug 102 made of tungsten is surrounded by an interlayer film 101 formed by deposition of a dielectric such as SiO₂.

Since there is the thin interlayer film 101 between the contact plug 102 and a wafer substrate 103 thereunder, resistance of the contact plug 102 relative to the wafer has a value of higher than 100 kΩ according to a thickness of the interlayer film 101. Such a resistance value R₀ has a specification, and is desirably 1 MΩ, for example. For example, a case where the resistance value R₀ is different from the specification value by 10% or more is determined to be defective.

An SEM image 110 of the sample 100 has three regions. A first region 111 and a second region 112 correspond to the interlayer film 101 and the contact plug 102, respectively. A third region 113 is located at a boundary between the first region 111 and the second region 112, and is a part of the first region extending from the boundary to the first region 111.

In a voltage contrast method in the related art, a potential of the contact plug 102 charged by electron beam irradiation during SEM observation is estimated based on brightness of the second region 112, and the resistance value R₀ relative to the wafer substrate 103 is calculated or magnitude thereof relative to a comparison target is determined. However, a change in the brightness of the second region 112 due to a difference in the resistance value R₀ is small, and measurement sensitivity of the resistance value R₀ may be low. Therefore, a method for measuring the resistance value R₀ with higher sensitivity is desired. In one embodiment in this description, focusing on the fact that the third region 113 depends on the resistance value R₀, the resistance value R₀ is calculated based on a feature shape of the third region 113.

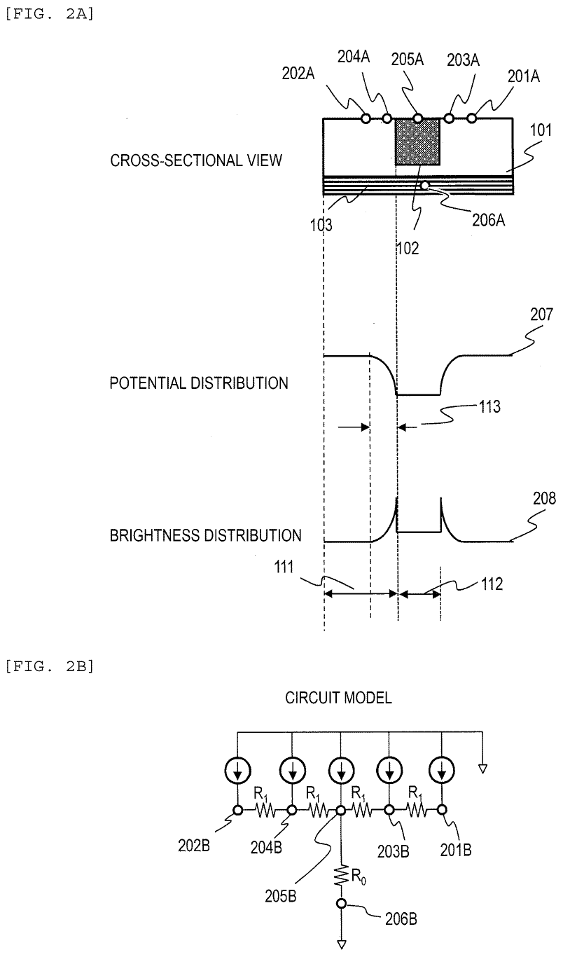

Here, a mechanism by which the third region 113 occurs in the SEM image will be described with reference to FIG. 2A and FIG. 2B. FIG. 2A shows a cross-sectional view of the sample 100, a surface voltage distribution at the time of SEM imaging corresponding thereto, and a brightness distribution on the SEM image. FIG. 2B shows an example of an electric circuit model. The circuit model shows six representative positions of the sample 100 and electrical relationships thereof.

Positions 201A to 204A are located at a surface of the interlayer film 101, a position 205A is located at a surface of the contact plug 102, and a position 206A is located at the wafer substrate 103. Nodes 201B to 206B are nodes of a circuit corresponding to the positions 201A to 206A. Resistance R₁ is resistance between the shown nodes and is calculated from resistivity ρ₁ of the interlayer film 101 and coordinates of the positions 201A to 204A. Sheet resistance may be used to represent an electrical characteristic of the interlayer film 101. Here, an insulating film distance between the nodes is constant, and resistance between the nodes 201B to 205B is approximated as the resistance R₁ having the same value. The resistance R₀ is resistance between the contact plug 102 and the wafer substrate 103, and includes resistance values of the interlayer film 101 interposed therebetween and the contact plug 102. A current source connected to the nodes 201B to 205B represents a current flowing when the positions 201A to 205A are irradiated with an electron beam.

Potentials of the nodes 203B and 204B are higher than a potential of the node 205B corresponding to the plug potential, and potentials of the nodes 201B and 202B far from the contact plug 102 are further higher. That is, a potential of a surface of the sample 100 has a potential distribution 207, and there is a region where the potential changes outside the contact plug 102. A brightness distribution of an SEM image acquired in the potential distribution 207 is a brightness distribution 208.

Since the secondary electron emission amount of the dielectric is larger than that of the conductor, brightness of the interlayer film 101 adjacent to the contact plug 102 is higher than brightness of the contact plug 102. A potential of the interlayer film 101 at a position away from the contact plug 102 increases due to resistance based on the resistance R₁. When the potential of the dielectric increases, secondary electrons are returned to the sample, and thus brightness of the SEM image decreases. Based on a relationship between a sample potential and a secondary electron detection rate, the brightness distribution of the SEM image corresponding to the potential distribution 207 is the brightness distribution 208.

A high-brightness region outside the contact plug 102 is the third region 113. The brightness of the third region 113 and the feature shape thereof depend on the resistance value R₁, the resistance value R₀, an electron beam current of the SEM, and the like. If a relationship between the brightness of the SEM image and the resistance value R₁, the electron beam current, and the sample potential is known, the resistance value R₀ can be estimated based on the feature shape of the third region 113. However, as in an SEM in the related art, the feature shape depends on not only the above-described electrical factors but also shape factors such as a plug shape of the contact plug 102.

In order to extract only an electrical element, it is necessary to subtract the shape factors. Therefore, in order to extract an electrical characteristic intended by the embodiment, feature shape analysis of the third region 113 in two or more potential distributions 207 is required.

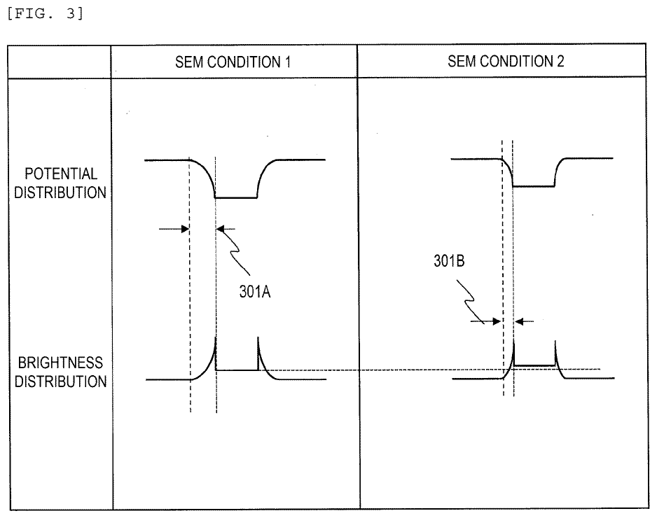

FIG. 3 shows brightness distributions generated under two different SEM imaging conditions. Under an SEM condition 2, a charge amount of the contact plug 102 is larger and a potential is higher than those under an SEM condition 1. As a result, a width 301A of the third region under the SEM condition 1 is larger than a width 301B of the third region under the SEM condition 2. This difference reflects an electrical characteristic of the sample, and the resistance value R₀ can be calculated by analysis based on the circuit model in FIG. 2.

The circuit model shown in the embodiment is a simple model and thus a resistance value along the surface of the sample 100 is represented by one value, that is, the resistance value R₁, and measurement accuracy can be improved using different resistance values according to selection of a sample shape or a position. The number of positions and circuit nodes on the sample used for calculation may be more or less than five. In the circuit model, potentials may be treated not as potentials at discrete positions but as a continuous potential shape represented by an analytical expression.

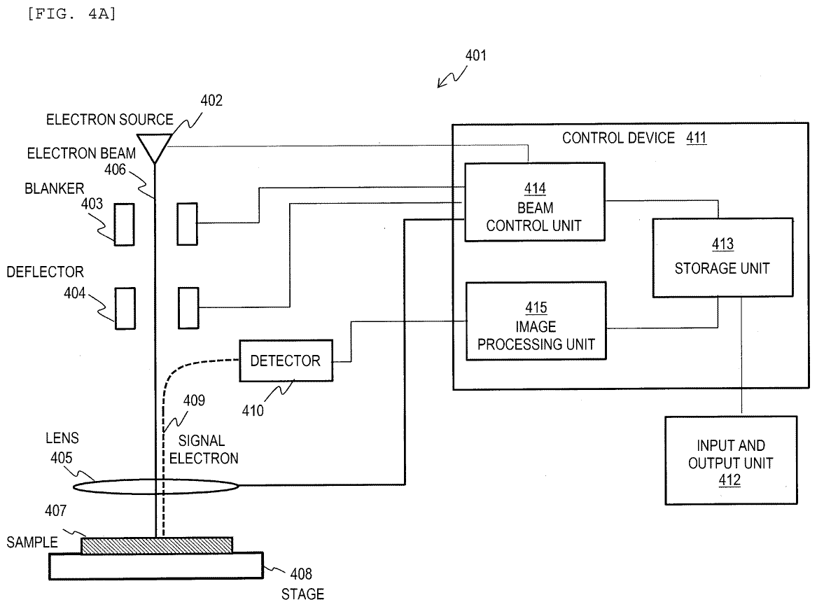

FIG. 4A shows an example of a device configuration according to the embodiment. A charged particle beam device 401 includes a charged particle optical system (electron optical system), a stage mechanism system, a control device 411, and an input and output unit 412. The control device 411 includes a beam control unit 414, an image processing unit 415, and a storage unit 413.

The charged particle optical system includes an electron source 402, a blanker 403 that pulses an electron beam 406 from the electron source 402, a deflector 404, an electron lens 405, and a signal electron detector 410. The stage mechanism system includes an XY stage (sample stage) 408 where a sample 407 to be inspected is placed. The charged particle optical system and the stage mechanism system are disposed in vacuum and controlled by the beam control unit 414.

FIG. 4B shows a configuration example of the image processing unit 415. The image processing unit 415 includes an image generation unit 416, a region storage unit 417, a region extraction unit 418, and a feature extraction unit 419. Referring back to FIG. 4A, the input and output unit 412 includes a mouse, a keyboard, and a display necessary for observation condition input and result displaying of the SEM. Information received from the input and output unit 412 and information output from the image processing unit 415 are stored by the storage unit 413. The beam control unit 414 controls the charged particle optical system based on received information.

The control device 411 may include a processor (CPU), a memory, an auxiliary storage device, an input and output port, a network interface, and a bus. The number of each component is as desired. The processor functions as the beam control unit 414 and the image processing unit 415 that provide predetermined functions by executing processing according to a program loaded in the memory. As the memory, for example, a volatile storage medium such as a DRAM can be used.

The auxiliary storage device stores data and programs used in the storage unit 413. As the auxiliary storage device, for example, a non-volatile storage medium such as a hard disk drive (HDD) or a solid state drive (SSD) is used. The input and output port is connected to an output device such as a keyboard, a pointing device, or a display (display device) of the input and output unit 412, and exchanges signals between the control device 411 and the input and output unit 412. The network interface enables communication with another information processing device via a network. These components of the control device 411 are communicably connected to each other by the bus.

Next, a principle of acquiring the SEM image will be described. The electron beam 406 emitted from the electron source 402 is focused by the lens 405 and emitted to the sample 407. An irradiation position and an irradiation range (for example, magnification) on the sample are controlled by the deflector 404. An acceleration voltage, an irradiation current, an irradiation position, and the like of the electron beam 406 are controlled by the beam control unit 414 based on information input by a user using the input and output unit 412.

A signal electron 409 generated by irradiating the sample 407 with the electron beam 406 is detected by the detector 410. The detector 410 outputs a voltage signal corresponding to an amount of the detected signal electron 409.

The image generation unit 416 of the image processing unit 415 generates the SEM image by two-dimensionally arranging the output signal of the detector 410 corresponding to the irradiation position of the electron beam 406 on the sample 407. The third region 113 in the SEM image is extracted from the SEM image by the region extraction unit 418 based on information stored in the region storage unit 417, and a feature shape and a feature thereof are calculated from a brightness profile by the feature extraction unit 419.

In order to determine the third region, the region storage unit 417 compares the SEM image with experimental image data of the sample, CAD data of the sample, pattern data of the sample, or the like. The experimental image data is a backscattered electron (BSE) image acquired by detecting signal electrons (BSEs) having high energy of, for example, 50 eV or more. Even when a boundary defining the third region 113 in a secondary electron image is unclear, the third region 113 can be specified using a clear boundary in the BSE image of the same field of view. The SEM image and the feature thus output are stored in the storage unit 413 or displayed by the input and output unit 412.

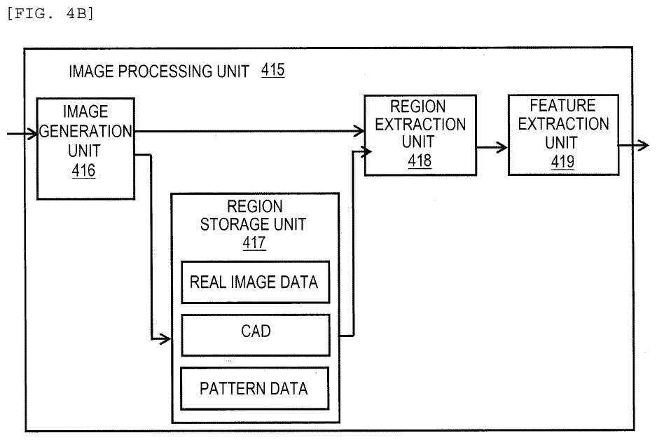

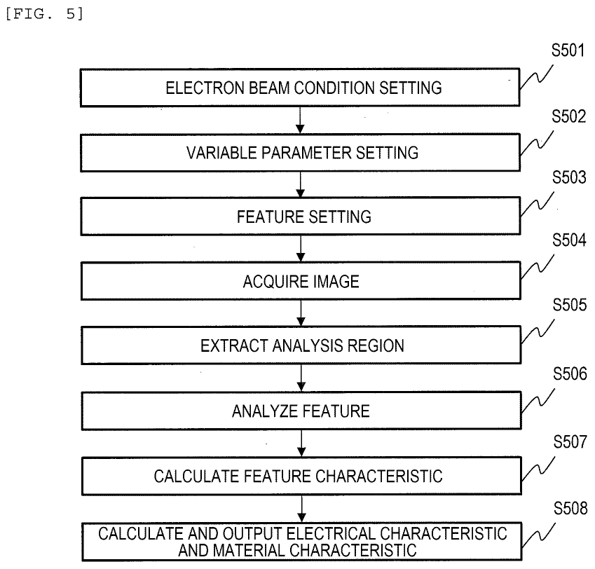

A specific inspection procedure of the embodiment will be described. FIG. 5 is a flowchart showing the inspection procedure. First, in step S501, the user sets an SEM electron beam condition. The user sets, using an electron beam condition setting GUI 601 shown in FIG. 6, an SEM observation condition such as an acceleration voltage, an irradiation current, a scanning speed, and a magnification of an electron beam. The input and output unit 412 receives setting information and stores the setting information in the storage unit 413.

Next, in step S502, the user performs variable parameter setting for acquiring SEM images under a plurality of conditions using a variable parameter setting GUI 602 shown in FIG. 6. Only two of a plurality of conditions are shown here. The input and output unit 412 receives setting information and stores the setting information in the storage unit 413. In this embodiment, an electron beam modulation condition is a variable parameter in order to create different potential states of the sample. The blanker 403 in FIG. 4 pulses the electron beam 406 based on a period and an irradiation time set under the electron beam modulation condition, and intermittently irradiates the sample 407.

FIG. 7 shows an electron beam irradiation sequence under conditions 1 and 2. A sequence diagram 701 shows a change over time in an electron beam current under the condition 1. The sample is irradiated with an electron beam pulse having a constant period and a constant irradiation time. A sequence diagram 702 shows a change over time in the electron beam current under the condition 2. The sample is irradiated with an electron beam pulse having a constant period and a constant irradiation time. The period under the condition 1 is shorter than the period under the condition 2, and the irradiation time (a time width of each pulse) is the same. SEM images having different sample charging states can be acquired using different periods. One or both of the period and the irradiation time of the pulse may differ under different irradiation conditions. The variable parameter may be another parameter that can change the sample charging state, such as the irradiation current or the scanning speed of the electron beam.

Next, in step 503, the user sets the feature to be extracted from the SEM image using a feature setting GUI 603 in FIG. 6. The input and output unit 412 receives setting information and stores the setting information in the storage unit 413. In the embodiment, an edge width obtained by calculating a width of the feature shape of the third region based on Algorithm 1 specified by the user is selected as the feature to be extracted. Algorithm 1 includes a method for calculating the third region, a method for converting the feature shape into a width value, and the like.

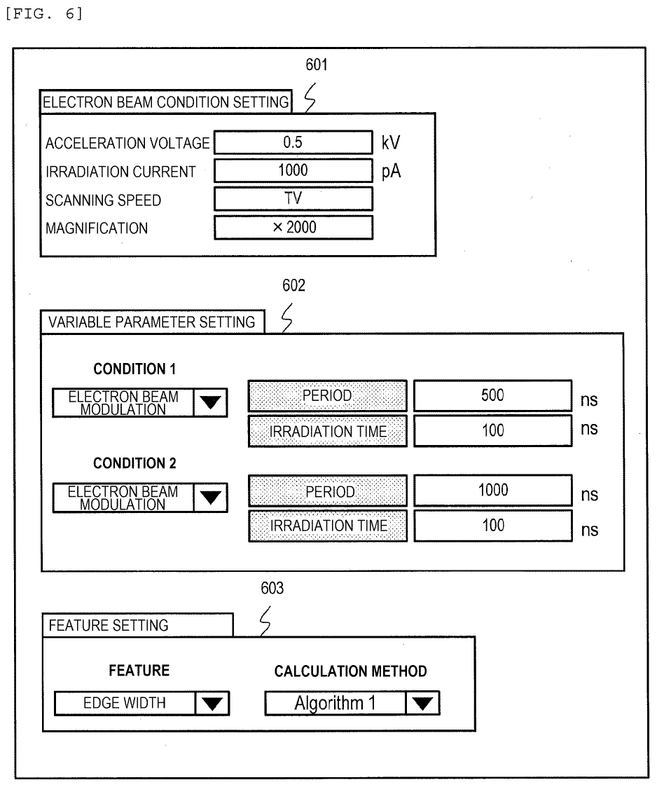

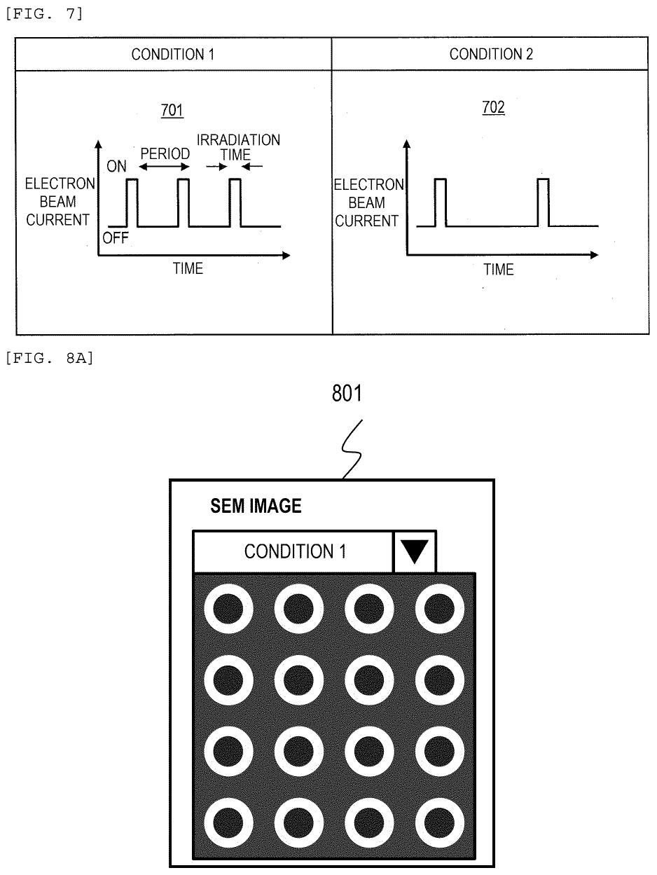

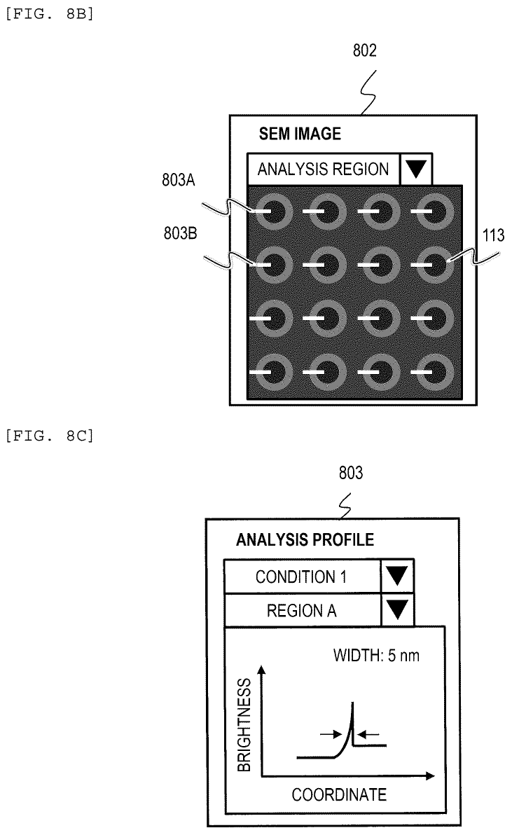

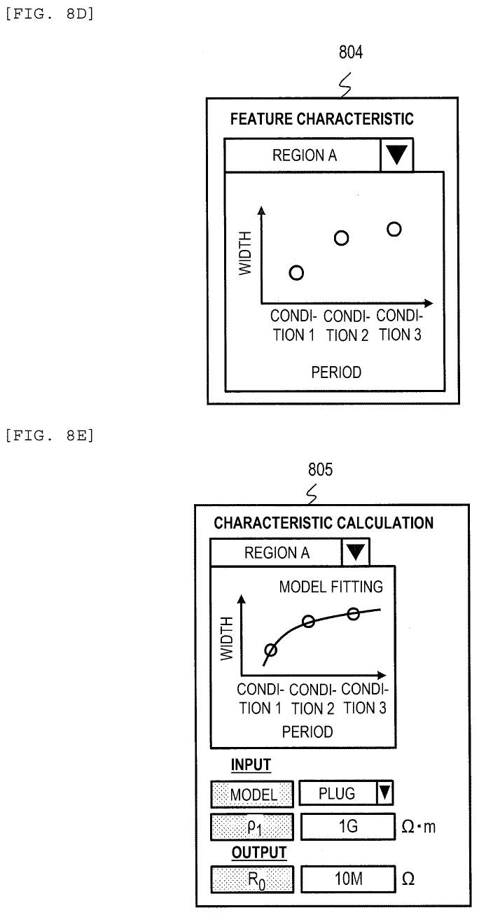

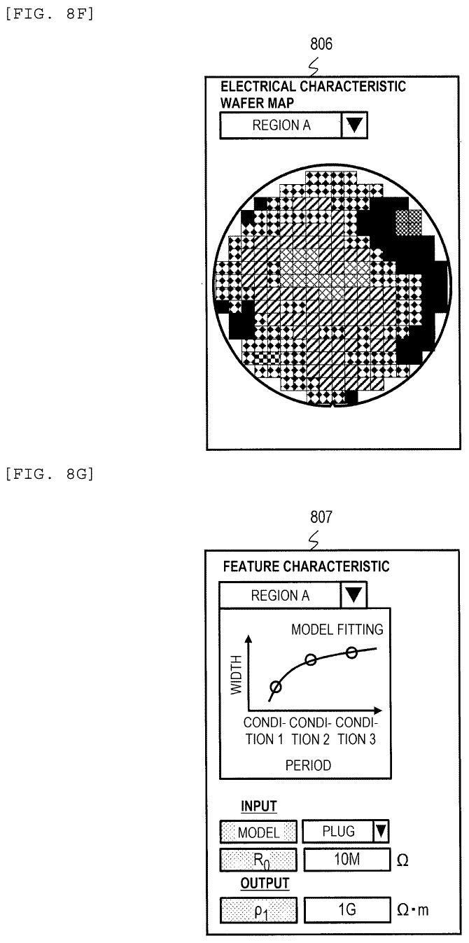

In step S504, the control device 411 acquires the SEM image based on the conditions set in S501 and S502. That is, the beam control unit 414 controls the charged particle optical system according to the setting information stored in the storage unit 413, and the image generation unit 416 of the image processing unit 415 generates the SEM image according to detection by the detector 410. The input and output unit 412 displays the SEM image. FIG. 8A shows an SEM image GUI 801 for displaying the SEM image. The SEM image is under a condition that there are a plurality of contact plugs 102 in a field of view in the sample shown in FIG. 1.

Next, in step S505, the region extraction unit 418 extracts an analysis region from the acquired SEM image with reference to data in the region storage unit 417. FIG. 8B shows an SEM image GUI 802 generated by the region extraction unit 418 and displayed by the input and output unit 412. On the SEM image GUI 802, analysis regions 803A and 803B for measuring the feature shape of the third region 113 are displayed. Two of a plurality of analysis regions are indicated as examples by reference signs 803A and 803B.

In step S506, the feature extraction unit 419 analyzes the feature. The feature extraction unit 419 extracts feature shapes indicating brightness of SEM images in the analysis regions 803A and 803B, and displays the feature shapes on an analysis profile GUI 803 via the input and output unit 412. FIG. 8C shows an example of the analysis profile GUI 803. In this example, the feature extraction unit 419 calculates a width of each feature shape and presents the width on the analysis profile GUI 803.

Next, in step S507, the feature extraction unit 419 calculates dependence of the calculated feature on the variable parameter and outputs the dependence to a feature characteristic GUI 804 shown in FIG. 8D. In the example shown in FIG. 8D, the feature extraction unit 419 generates a graph indicating a relationship between the period, which is the variable parameter, and the width of the feature shape, and displays the graph on the feature characteristic GUI 804.

Finally, in step S508, the feature extraction unit 419 calculates and outputs an electrical characteristic. Specifically, the feature extraction unit 419 applies a model specified by the user to the feature characteristic calculated in step S507 and outputs an electrical characteristic value using necessary information input by the user.

FIG. 8E shows a characteristic calculation GUI 805. In the example of the characteristic calculation GUI 805 in FIG. 8E, the user selects a “plug” model meaning the circuit model in FIG. 2B, and assumes or separately measures and inputs the resistivity ρ₁, which is a parameter necessary for calculating the electrical characteristic, or the resistance value R₁ converted therefrom. The feature extraction unit 419 outputs the resistance value R₀ at which the feature characteristic estimated by the model is close to an experimental value, that is, the resistance between the contact plug 102 and the wafer substrate 103. Here, one feature of the embodiment is that the feature characteristic is calculated based on a relationship between the feature shape of the SEM image and the imaging condition of the SEM image.

In the voltage contrast method used in electrical characteristic inspection in the related art, brightness of a specific pixel or pixel group of the SEM image is used to calculate the electrical characteristic. That is, in the method in the related art, an analysis target is a curve with the imaging condition on a horizontal axis and the brightness on a vertical axis, whereas in the embodiment, the analysis target (a value on the vertical axis) is a shape feature such as the width of the feature shape.

As described above, the electrical characteristic of the contact plug can be calculated based on the feature shape of the third region in the SEM images under the plurality of conditions. Presence or absence of a contact plug defect can be determined based on the calculated electrical characteristic value. Step S503 and step S504 may be performed in any order.

An in-plane distribution can be measured by measuring a large number of electrical characteristic values of the contact plug as described above within a surface of the semiconductor wafer. FIG. 8F shows an example of an electrical characteristic wafer map GUI 806 indicating an in-wafer distribution of resistance values. Not only an absolute value of the resistance but also the in-wafer distribution can be used to detect an abnormality in a film forming or processing device used for device manufacturing.

As a modification of the first embodiment, an example of calculating an electrical characteristic of the dielectric of the sample 100 will be described. Since steps up to step 507 are the same as those described above, description thereof will be omitted. As indicated by a feature characteristic GUI 807 in FIG. 8G, in this example, the resistance value of the contact plug is received by a model in step S508, and resistivity of the dielectric is calculated. The resistivity of the dielectric represents an electrical characteristic of a material of the insulating film. Therefore, not only the electrical characteristic of the contact plug but also the electrical characteristic of the material of the interlayer film around the contact plug can be calculated according to an input condition.

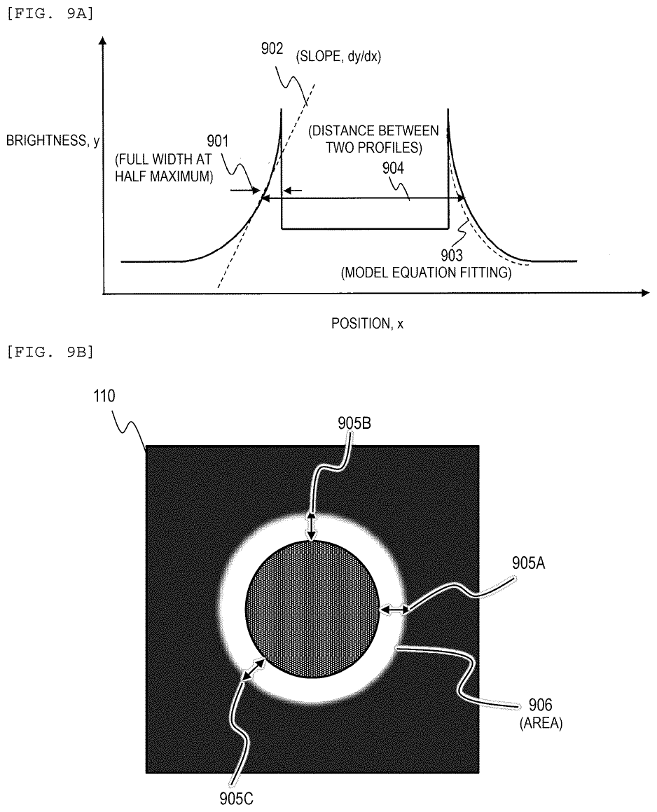

In the embodiment, the width of the feature shape is measured as the feature to be extracted by evaluating the feature shape of the third region 113. However, the feature of the feature shape is not limited thereto. FIG. 9A shows another feature example. FIG. 9A is an example of the feature shape of the third region 113. In addition to a width 901, the feature may be a slope 902, a second derivative, or a fitting parameter necessary for fitting 903 of a model equation.

For example, an exponential function shown in equation 1 may be used for the fitting 903, and C₁ indicating a decay rate may be used as the feature. Alternatively, a parameter extracted by fitting a Gaussian distribution shown in equation 2 or an error function shown in equation 3 to a decay portion of the brightness profile may be used as the feature. Alternatively, a distance between two feature shapes indicated by a distance 904 may be used as the feature.

$$y = {A}_{1} \cdot {e}^{- ( x - {B}_{1} ) / {C}_{1}} + {D}_{1} \qquad [ Math . 1 ]$$

$$y = {A}_{2} \cdot {e}^{- {( x - {B}_{2} )}^{2} / ( 2 {C}_{2} )} + {D}_{2} \qquad [ Math . 2 ]$$

$$y = {A}_{3} \cdot erf ( [ x - {B}_{2} ] / {C}_{3} ) + {D}_{3} \qquad [ Math . 3 ]$$

In the embodiment, the feature is evaluated based on the feature shape in a horizontal direction of the third region generated in the SEM image. As shown in FIG. 9B, instead of a feature shape 905A in the horizontal direction, a feature shape 905B in a vertical direction or a feature shape 905C in a diagonal direction may be used, or feature shapes in a plurality of directions may be evaluated in each third region. As indicated by an area 906, an area or roundness of the third region may be used as the feature instead of the feature shape.

In the embodiment, a part of the first region 111 extending from the boundary between the first region 111 and the second region 112 toward the first region 111 is used as an example of the third region 113. However, this phenomenon depends on a material and a shape of the sample 100, and thus is not limited thereto. The third region 113 may be a part of the second region 112 extending from the boundary to the second region 112, or may be a region extending from the boundary to both the first region 111 and the second region 112.

Although the circuit model in FIG. 2B used in the embodiment includes only a resistor and a current source, a capacitor may be added to the circuit model in order to reflect a transient sample potential change caused by intermittent irradiation with the electron beam. In this case, a capacitance value of the sample can be calculated by fitting an improved circuit model to the feature calculated by the device configuration and the inspection flow in the embodiment.

Using the first embodiment, the electrical characteristic of the contact plug and the material characteristic of the interlayer film around the contact plug can be inspected by extracting the feature from the feature shape of the third region generated on the SEM image at the boundary between the first region (a dielectric region such as the interlayer film) and the second region (a conductor or a semiconductor pattern such as the contact plug) and in the vicinity thereof, calculating the feature characteristic depending on the SEM imaging condition, and comparing the feature characteristic with the model. The material characteristic is a characteristic specific to a material, and includes not only a characteristic indicating an electrical response but also a characteristic specific to a material such as a band offset to be described later.

### Second Embodiment

In the first embodiment, the feature shape of the third region in a plurality of sample charging states is evaluated by changing the irradiation condition of the electron beam. However, in a case where resistance of the contact plug is high or in a case where the interlayer film is likely to accumulate charge due to traps, when irradiated with the electron beam, a charging history remains, and it is difficult to control the charging state with high reproducibility. A method is also desired for generating the third region with high accuracy in such a sample as well. In this embodiment, a method for controlling a sample potential using laser and evaluating the electrical characteristic will be described.

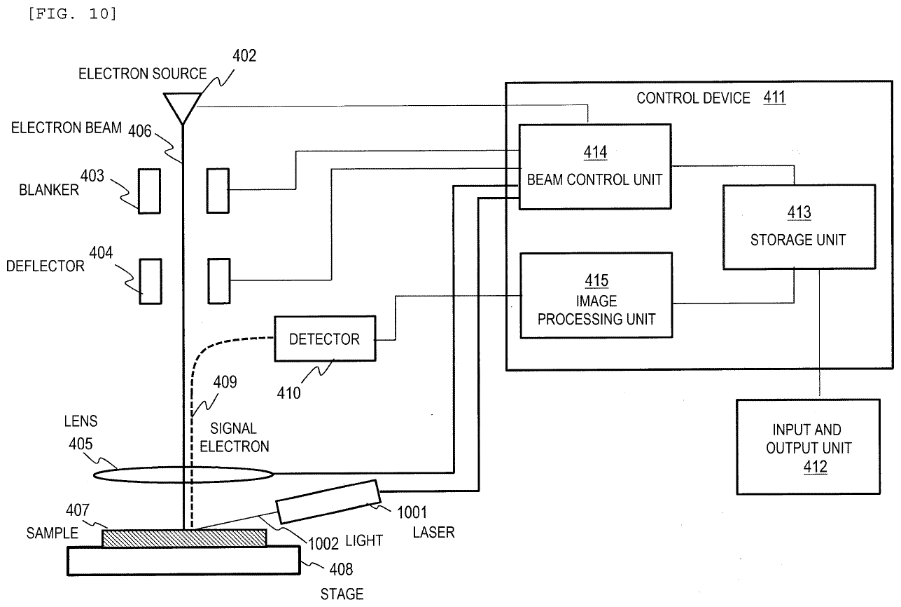

FIG. 10 shows a device configuration of the embodiment. In FIG. 10, laser 1001 is added to the basic device configuration in FIG. 4. Output, a wavelength, deflection, and ON/OFF of the laser 1001 are controlled by the beam control unit 414. Light 1002 output from the laser 1001 is emitted to the same position as the electron beam 406 on the sample 407. The laser 1001 outputs, for example, ultraviolet light having a wavelength of 400 nm or less. It is known that the ultraviolet light neutralizes the insulating film charged by the electron beam to stabilize the sample potential. In the embodiment, the sample potential is controlled using the laser 1001, the third region 113 is evaluated, and the resistance between the contact plug 102 and the wafer substrate 103 is measured.

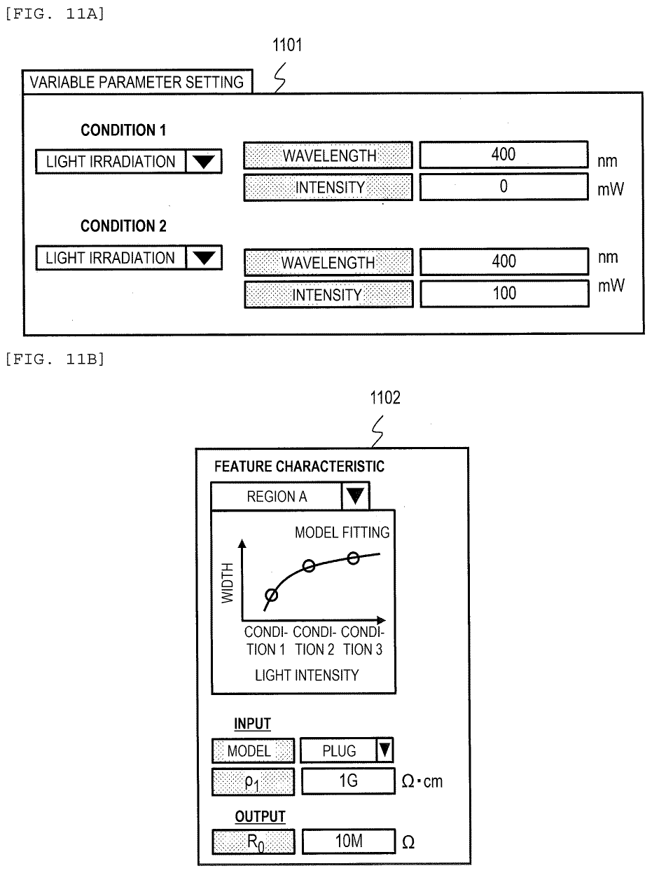

An inspection procedure of the embodiment will be described. The inspection procedure is different from FIG. 5 only in step S502. When setting the variable parameter in step S502, a light irradiation condition is the variable parameter as shown on a variable parameter setting GUI 1101 in FIG. 11A. Two of a plurality of conditions are shown. In contrast to irradiation intensity of 0 mW (no irradiation) under the condition 1, irradiation intensity under the condition 2 is 100 mW, and a neutralization effect acts on the sample.

Results of calculating the feature characteristic in step S507 and calculating the electrical characteristic in step S508 by the feature extraction unit 419 are shown on a feature characteristic GUI 1102 in FIG. 11B. The model selected in the embodiment is a circuit model (not shown) in consideration of the neutralization effect of light irradiation. The resistance value between the contact plug 102 and the wafer substrate 103 is calculated and output by fitting the model to a relationship between laser intensity and the width of the feature shape and inputting the resistivity ρ₁ of the interlayer film.

In the embodiment, the laser is used to control the sample potential, and alternatively, an LED, a white light source, or white light monochromatized using a monochromator may be used as a light source. Using the second embodiment, it is possible to inspect the electrical characteristic even in a sample where charging is not stable due to electron beam irradiation.

### Third Embodiment

In the first and second embodiments, the electrical and material characteristics such as the resistance value and the resistivity of the sample are calculated and inspected. In this embodiment, a method for measuring a band offset that is a characteristic of a material interface (material characteristic) will be described.

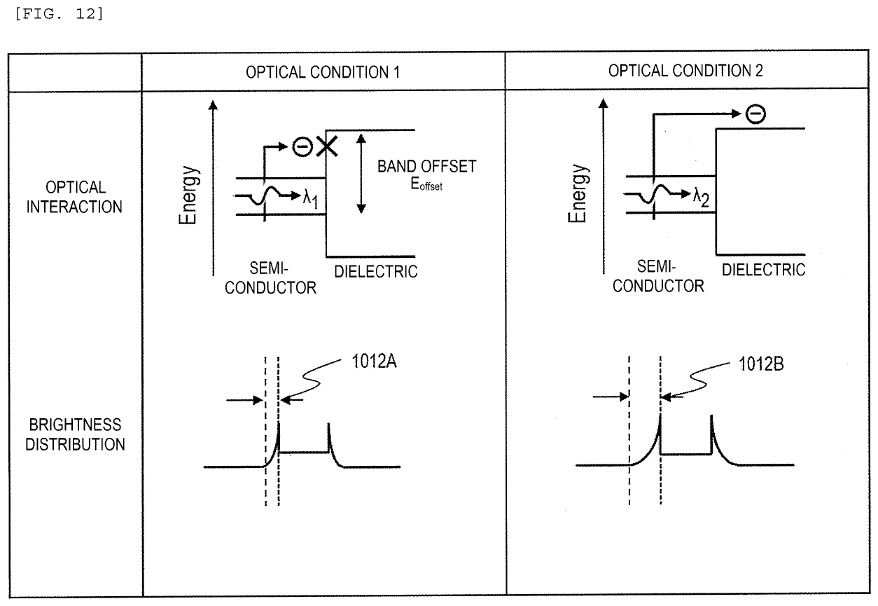

A principle of measuring the band offset will be described with reference to FIG. 12. FIG. 12 shows a physical phenomenon caused by irradiating a semiconductor or dielectric interface with light and a brightness feature shape of an SEM image obtained at that time. The sample is the sample 100 in FIG. 1. The band offset is a difference between energy levels of two types of materials at a material interface. In FIG. 12, the band offset is a difference between an energy level of a valence band of a semiconductor and an energy level of a conduction band of a dielectric. By irradiating with light, electrons in the valence band of the semiconductor absorb photons and are excited.

Under an optical condition 1, energy of electrons excited by photons having a wavelength λ1 is lower than the energy level of the conduction band of the dielectric. Under an optical condition 2, energy of electrons excited by photons having a wavelength λ2 shorter than λ1 is higher than the energy level of the conduction band of the dielectric. That is, the electrons can be injected from the semiconductor into the dielectric by irradiating the sample with light having the wavelength λ2. This phenomenon is known as an internal photoemission effect.

When the dielectric is charged by the electron beam as in the first embodiment, it is possible to neutralize the dielectric by irradiating with the light having the wavelength λ2. As a result, a width of a third region 1012B in an SEM image acquired under the optical condition 2 under which neutralization is available is wider than a width of a third region 1012A of an SEM image acquired under the optical condition 1 under which neutralization is not available. A wavelength where the internal photoemission effect is available is determined by the band offset reflecting an interface material and film quality thereof. Thus, the band offset can be calculated based on a relationship between the third region in the SEM image and the wavelength of the emitted light.

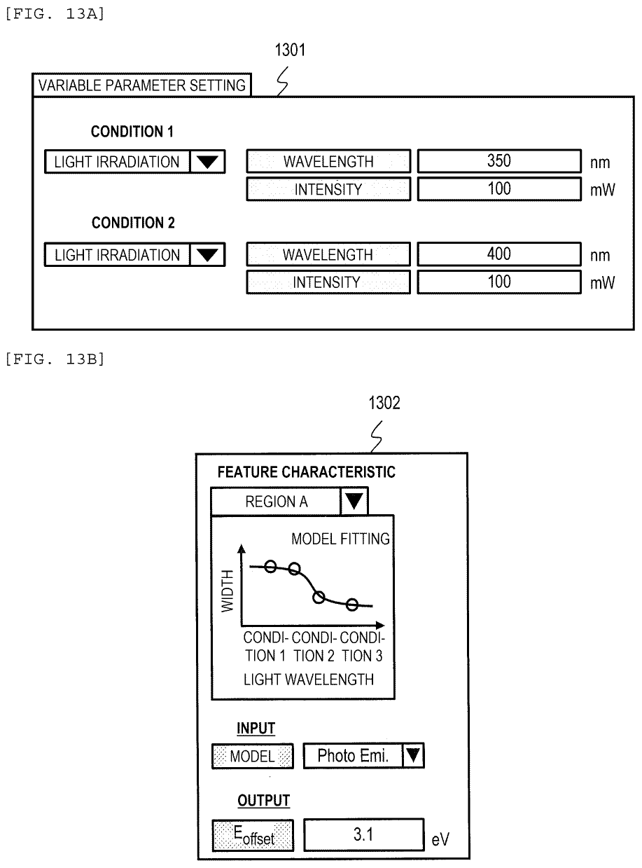

A calculation procedure of the band offset will be described. This procedure is different from that in the first embodiment only in steps S502 and S508 in FIG. 5. Here, only these two different steps will be described. The variable parameter setting in step S502 is performed using a variable parameter setting GUI 1301 in FIG. 13A. The variable parameter is a light irradiation condition, and a different wavelength is set for each condition. In the embodiment, only wavelengths of 350 nm and 400 nm are shown, but the wavelengths are not limited thereto.

An example in which the feature extraction unit 419 extracts the feature characteristic from the SEM image captured according to the variable parameter is displayed on a feature characteristic GUI 1302 in FIG. 13B. In the displayed graph, a horizontal axis represents the wavelength, and a vertical axis represents the width of the SEM image feature shape. Under a long wavelength condition, the width is small, which reflects that the dielectric film is not neutralized. In this graph, “PhotoEmi.”, which is a model equation of the internal photoemission effect, is selected and fitted to the feature characteristic. As a result, a wavelength where the dielectric film can be neutralized, that is, the band offset is determined and output.

As described above, the band offset that is the interface material characteristic is calculated based on dependence of the feature shape of the third region on the emitted light wavelength. As the light source used in the embodiment, any of an LED, laser, or white light monochromatized using a monochromator may be used as long as the wavelength can be changed or selected. According to the third embodiment, film quality of the contact plug or the dielectric adjacent thereto can be inspected based on measurement of the band offset.

### Fourth Embodiment

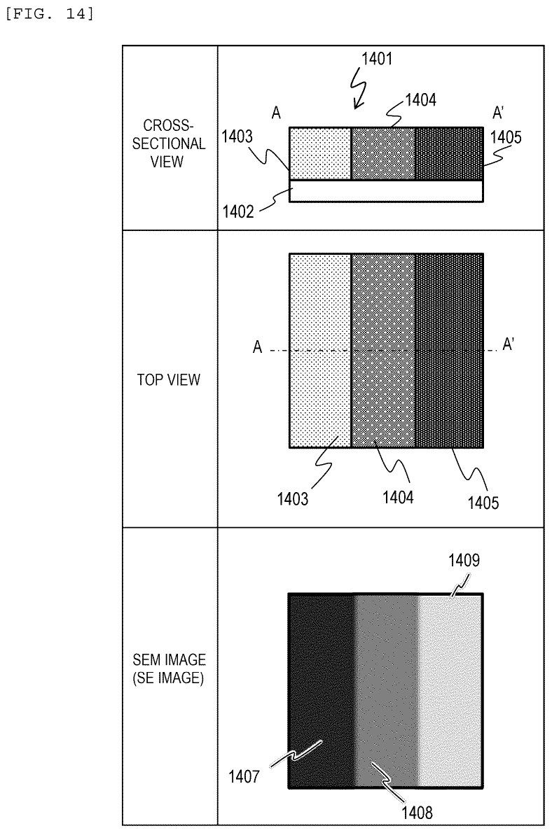

In this embodiment, a procedure for inspecting a dopant concentration of a semiconductor will be described. FIG. 14 shows an example of a sample 1401 to be inspected. FIG. 14 is a cross-sectional view, a top view, and an SEM image acquired by an SEM of the sample 1401. The cross-sectional view shows a cross-section taken along line AA′ in the top view. In the sample 1401, three regions of Si 1403 to 1405 having different doping concentrations are formed on a dielectric 1402. The Si 1403 is n+ type, the Si 1404 is close to intrinsic p-type, the Si 1405 is p+ type, and the three semiconductors have different electrical characteristics.

An SEM image of the sample 1401 shows three different brightness regions 1407 to 1409. In the SEM image, the p-type appears bright, while the n-type appears dark, creating a contrast. An interface between Si 1403 and Si 1404 and an interface between Si 1404 and Si 1405 are semiconductor junctions, and a depletion layer is generated in the vicinity thereof. Since a potential of a sample surface continuously changes in the depletion layer region, the brightness changes gradually at boundaries between the three brightness regions. It is known that when irradiated with light, a photocurrent is generated at a semiconductor junction, and the potential and the depletion layer of the semiconductor change. In the embodiment, the dopant concentration of the semiconductor is inspected using this phenomenon. The dopant concentration is one of electrical characteristics that affect resistance of the region.

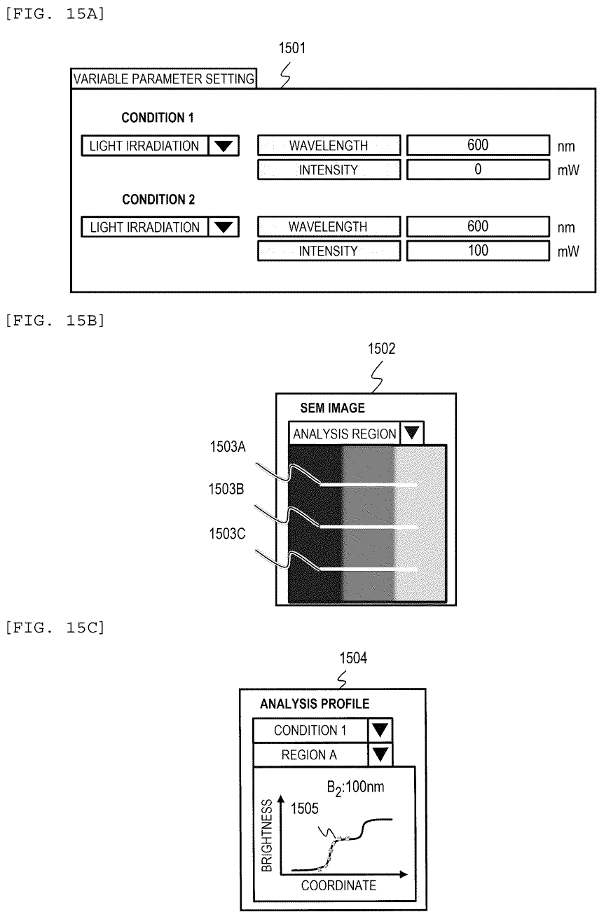

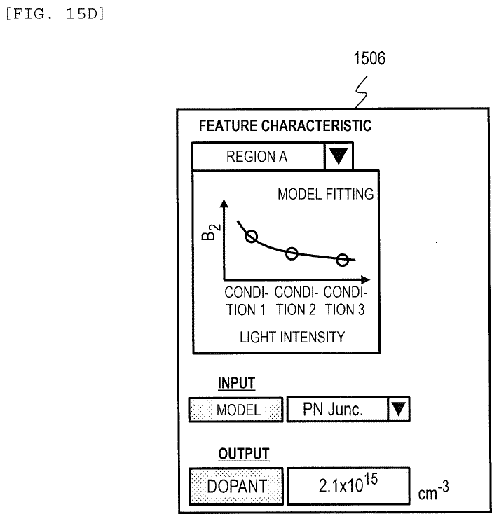

In the semiconductor doping concentration inspection, only differences from the flowchart in the first embodiment will be described. In step S502, different light irradiation conditions are set as variable parameters using a variable parameter setting GUI 1501 in FIG. 15A. The wavelength was set to 600 nm at which Si absorbs light. Light irradiation intensity changes under each condition.

The acquired SEM image and a result of analysis region extraction in step S504 are shown on an SEM image GUI 1502 in FIG. 15B. Three analysis regions 1503A to 1503C are shown. A feature shape of the analysis region 1503A, which is one thereof, is shown on an analysis profile GUI 1504 in FIG. 15C. The stepwise feature shape reflects brightness of the three regions 1503A to 1503C. In this embodiment, a doping concentration of Si 1404 is calculated based on dependence of a position of the interface between Si 1403 and Si 1404 on light irradiation.

As described above, the depletion layer at the interface is deformed due to light irradiation, and a position between the brightness regions 1407 and 1408 on the SEM image changes. A boundary between the brightness regions 1407 and 1408 is calculated by fitting an error function 1505 in equation 3 to the feature shape. B2 in equation 3 is a parameter representing the boundary position.

On a feature characteristic GUI 1506 in FIG. 15D, a relationship between the extracted parameter B2 and light intensity that is an imaging condition is displayed. The user selects a model “PN Junc.” that is a junction contrast model. Since a feature characteristic of the model is determined only by the dopant concentration, a dopant concentration of the Si 1404 is calculated and displayed by fitting to the acquired feature characteristic. As described above, the dopant concentration, which is a material characteristic of the semiconductor, is calculated based on the dependence of the feature shape of the SEM image on the emitted light wavelength.

According to the fourth embodiment, quality of the semiconductor used as a channel material of a contact plug or a transistor can be inspected based on the measurement of the dopant concentration.

The invention is not limited to the embodiments described above, and includes various modifications. For example, the embodiments described above have been described in detail to facilitate understanding of the invention, and the invention is not necessarily limited to those including all configurations described above. A part of a configuration of a certain embodiment can be replaced with a configuration of another embodiment, and a configuration of another embodiment can be added to a configuration of a certain embodiment. It is possible to add, delete, or replace a part of configurations of each embodiment with other configurations.

A part or all of configurations, functions, processing units, and the like described above may be implemented by hardware by, for example, designing with an integrated circuit. The above configurations, functions, and the like may be implemented by software by a processor interpreting and executing a program for implementing each function. Information such as a program, a table, and a file for implementing each function can be stored in a recording device such as a memory, a hard disk, or a solid state drive (SSD), or in a recording medium such as an IC card or an SD card.

Further, control lines and information lines are those considered to be necessary for description, and not all control lines and information lines are necessarily shown in the product. Actually, it may be considered that almost all the configurations are connected to one another.

1. A charged particle beam device comprising:
a charged particle source configured to irradiate a sample with a charged particle beam;
a detector configured to detect a secondary electron generated from the sample due to the irradiation with the charged particle beam;
a deflector configured to deflect the charged particle beam; and
an image processing device configured to generate an image based on irradiation position information on the charged particle beam on the sample and detection intensity by the detector, wherein
the image processing device
acquires images of the sample in different charging states of the sample,
measures a feature of a feature shape that occurs at a boundary between regions of different materials in each of the acquired images, and
estimates an electrical characteristic or a material characteristic of the sample based on the feature.

2. The charged particle beam device according to claim 1, wherein
the acquired images are images of the sample under different irradiation conditions of the charged particle beam.

3. The charged particle beam device according to claim 1, further comprising:
a light source configured to irradiate the sample with light, wherein
the acquired images are images of the sample under different irradiation conditions where an irradiation condition of at least one of the charged particle beam and the light differs.

4. The charged particle beam device according to claim 1, wherein
the feature includes at least one of a width, a slope, a second derivative, an area, roundness, and a fitting parameter of a fitting equation of the feature shape.

5. The charged particle beam device according to claim 1, wherein
the feature is a distance between a plurality of feature shapes in each of the acquired images.

6. The charged particle beam device according to claim 2, wherein
the irradiation condition of the charged particle beam is at least one of a period and an irradiation time of a pulse of the charged particle beam with which the sample is irradiated.

7. The charged particle beam device according to claim 3, wherein
the irradiation condition of the charged particle beam is at least one of a period and an irradiation time of a pulse of the charged particle beam with which the sample is irradiated.

8. The charged particle beam device according to claim 3,
wherein the irradiation condition of the light is presence or absence of the irradiation with the light.

9. The charged particle beam device according to claim 1, wherein
the electrical characteristic or the material characteristic of the sample includes at least one of a resistance value, a capacitance value, resistivity, a band offset, and a dopant concentration.

10. The charged particle beam device according to claim 1, wherein
the image processing device estimates the electrical characteristic or the material characteristic of the sample based on a comparison result between the feature and a model specified by a user.

11. The charged particle beam device according to claim 1, wherein
the image processing device displays the feature of each of the different charging states in a graph.

12. A method for estimating a characteristic of a sample including regions of different materials, the method comprising:
generating images of the sample in different charging states based on a secondary electron generated by scanning the sample in the different charging states with a charged particle beam;
measuring a feature of a feature shape that occurs at a boundary of the regions of the different materials in the images; and
estimating an electrical characteristic or a material characteristic of the sample based on the feature of the images in the different charging states.

13. The method according to claim 12, wherein
the images in the different charging states are generated under different irradiation conditions of the charged particle beam.

14. The method according to claim 12, wherein
the images in the different charging states are generated under different irradiation conditions where an irradiation condition of at least one of the charged particle beam and light differs.
